(19) United States
(12) Patent Application Publication
(10) Pub. No.: US 2024/0431127 A1
(43) Pub. Date: Dec. 26, 2024

(54) LIGHT DETECTION DEVICE AND MANUFACTURING METHOD THEREOF

(71) Applicant: Japan Display Inc., Tokyo (JP)

(72) Inventors: Motochika YUKAWA, Tokyo (JP); Yasushi TOMIOKA, Tokyo (JP)

(73) Assignee: Japan Display Inc., Tokyo (JP)

(21) Appl. No.: 18/743,602

(22) Filed: Jun. 14, 2024

(30) Foreign Application Priority Data
Jun. 20, 2023 (JP) 2023-101115

(51) Int. Cl. H10K 39/32; H10K 30/82; H10K 30/88; H10K 71/20; H10K 71/60; H10K 102/10

(52) U.S. Cl. CPC H10K 39/32; H10K 30/82; H10K 30/88; H10K 71/231; H10K 71/60; H10K 2102/103

(57) ABSTRACT

A light detection device includes a lower structure that is provided in a detection area and in a frame area surrounding the detection area, a plurality of pixel electrodes that are provided in array on the lower structure in the detection area, an organic photoelectric conversion layer that is provided on the plurality of pixel electrodes and continuously formed on the detection area and a part of the frame area, an upper electrode that is provided on the organic photoelectric conversion layer, and a transparent conductive protective layer that is provided on the lower structure in at least a part of the frame area and at least partially disposed under a part of a peripheral edge portion of the organic photoelectric conversion layer formed in the frame area.

### CROSS-REFERENCE TO RELATED APPLICATION

The present application claims priority from Japanese application No. 2023-101115 filed on Jun. 20, 2023, the content of which is hereby incorporated by reference into this application.

### BACKGROUND OF THE INVENTION

### 1. Field of the Invention

The present invention relates to a light detection device and a method for manufacturing the light detection device.

### 2. Description of the Related Art

In recent years, a detection device in which organic photodiodes (OPD) are arranged on a substrate has been known. Such a detection device is used as a biometric sensor for detecting biometric information, such as a fingerprint and a vein.

The detection device using an OPD includes a thin film transistor and an OPD layer that are formed on a substrate. The OPD layer is formed of a plurality of layers, including such as an organic light-receiving layer, disposed between the upper electrode and the lower electrode. For example, as disclosed in JP2021-68793A, an organic layer may be commonly provided on a plurality of lower electrodes. In this case, it is conceivable that the organic layer is provided over the entire substrate and then patterned so that the organic layer remains only on the lower electrodes.

However, if the etching condition is too weak when patterning the organic layer, a residue is generated, which causes intrusion of moisture. On the other hand, if the etching condition is increased so that no residue is generated, the lower structure is damaged, which causes an energization trouble.

### SUMMARY OF THE INVENTION

One or more embodiments of the present invention have been conceived in view of the above, and one of objects thereof is to provide a light detection device that facilitates patterning of organic layers and is improved in quality, and a method for manufacturing the light detection device.

### Solution to Problem

(1) A light detection device according to one aspect of the present invention includes a lower structure that is provided in a detection area and in a frame area surrounding the detection area, a plurality of pixel electrodes that are provided in array on the lower structure in the detection area, an organic photoelectric conversion layer that is provided on the plurality of pixel electrodes and continuously formed on the detection area and a part of the frame area, an upper electrode that is provided on the organic photoelectric conversion layer, and a transparent conductive protective layer that is provided on the lower structure in at least a part of the frame area and at least partially disposed under a part of a peripheral edge portion of the organic photoelectric conversion layer formed in the frame area.

(2) In the light detection device according to (1), the transparent conductive protective layer may be provided so as to surround the detection area, and the entire peripheral edge portion of the organic photoelectric conversion layer may be disposed in the frame area.

(3) The light detection device according to (1) or (2) may further include a sealing structure that includes a first inorganic layer, a resin layer, and a second inorganic layer, the first inorganic layer being provided on the upper electrode in the detection area and the frame area, the resin layer being provided on the first inorganic layer, the second inorganic layer being provided on the resin layer, and the transparent conductive protective layer may be disposed inside the second inorganic layer in a plan view.

(4) In the light detection device according to any one of (1) to (3), a common line connecting portion electrically connected to a common line may be provided on a surface of the lower structure in the frame area, a part of the transparent conductive protective layer may cover at least a part of the common line connecting portion, and the part of the transparent conductive protective layer that covers the common line connecting portion may be electrically connected to the upper electrode.

(5) In the light detection device according to any one of (1) to (4), the plurality of pixel electrodes and the transparent conductive protective layer may be made of a same material.

(6) In the light detection device according to any one of (1) to (5), the transparent conductive protective layer may be made of indium-based oxide.

(7) In the light detection device according to any one of (1) to (6), the transparent conductive protective layer may be made of indium-tin-oxide (ITO).

(8) A method for manufacturing a light detection device according to one aspect of the present invention includes the steps of forming a lower structure in a detection area and in a frame area surrounding the detection area, forming a plurality of pixel electrodes in array on the lower structure in the detection area, forming a transparent conductive protective layer in at least a part of the frame area on the lower structure so as to be adjacent to the detection area, etching the organic photoelectric conversion layer with a mask that covers the detection area and a part of an area in the frame area in which the transparent conductive protective layer is formed, and forming an upper electrode on the etched organic photoelectric conversion layer.

### BRIEF DESCRIPTION OF THE DRAWINGS

FIG. 1 is a block diagram schematically showing a configuration of a light detection device according to the present embodiment;

FIG. 2 is a block diagram showing an outline of a circuit configuration of the light detection device according to the present embodiment;

FIG. 3 is a plan view of the light detection device according to the present embodiment;

FIG. 4 is a cross-sectional view of the light detection device taken along the line IV-IV in FIG. 3;

FIG. 5 is a cross-sectional view of the light detection device taken along the line V-V in FIG. 3;

FIG. 6A is a cross-sectional view of the light detection device according to the present embodiment indicating a method of manufacturing the same;

FIG. 6B is a cross-sectional view of the light detection device indicating the method of manufacturing the same subsequent to the step of FIG. 6A;

FIG. 6C is a cross-sectional view of the light detection device indicating the method of manufacturing the same subsequent to the step of FIG. 6B;

FIG. 6D is a cross-sectional view of the light detection device indicating the method of manufacturing the same subsequent to the step of FIG. 6C;

FIG. 7 is a plan view of the light detection device according to a modification of the present embodiment;

FIG. 8 is a cross-sectional view of the light detection device taken along the line VIII-VIII in FIG. 7; and

FIG. 9 is a cross-sectional view of the light detection device taken along the line IX-IX in FIG. 7.

### DETAILED DESCRIPTION OF THE INVENTION

Embodiments of the present invention will be described in detail referring to the drawings. In this regard, the present invention is not to be limited to the embodiments described below, and can be changed as appropriate without departing from the spirit of the invention.

The accompanying drawings may schematically illustrate widths, thicknesses, shapes, or other characteristics of each part for clarity of illustration, compared to actual configurations. However, such a schematic illustration is merely an example and not intended to limit the present invention. In this specification and the drawings, some elements identical or similar to those shown previously are denoted by the same reference signs as the previously shown elements, and thus repetitive detailed descriptions of them may be omitted as appropriate.

Further, in the embodiments, when a positional relationship between a component and another component is defined, if not otherwise stated, the words “on” and “below” suggest not only a case where the another component is disposed immediately on or below the component, but also a case where the component is disposed on or below the another component with a third component interposed therebetween.

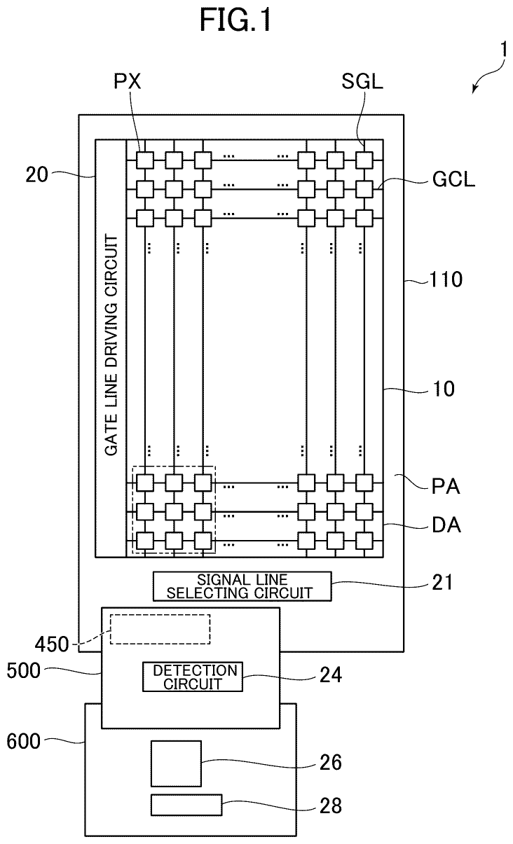

FIG. 1 is a block diagram schematically showing a configuration of a light detection device according to the present embodiment. As shown in FIG. 1, a light detection device 1 includes a substrate 110, a sensor unit 10, a gate line driving circuit 20, a signal line selecting circuit 21, a detection circuit 24, a control circuit 26, and a power supply circuit 28.

A control substrate 600 is electrically connected to the substrate 110 via a flexible printed board 500. The flexible printed board 500 includes the detection circuit 24. The control substrate 600 includes the control circuit 26 and the power supply circuit 28. The control circuit 26 is a field programmable gate array (FPGA), for example. The control circuit 26 supplies control signals to the sensor unit 10, the gate line driving circuit 20, and the signal line selecting circuit 21 so as to control the detection operation of the sensor unit 10. The power supply circuit 28 supplies a power supply voltage to the sensor unit 10, the gate line driving circuit 20, and the signal line selecting circuit 21.

The light detection device 1 includes a detection area DA and a frame area PA. The detection area DA is an area in which the sensor unit 10 is provided. The frame area PA is an area outside the detection area DA where the sensor unit 10 is not provided. In other words, the frame area PA is an area between the end portion of the detection area DA and the end portion of the substrate 110. The substrate 110 has a terminal portion 450 in an area in the lower side of the frame area PA. The substrate 110 and the flexible printed board 500 are electrically connected to each other via the terminal portion 450.

The sensor unit 10 includes a plurality of pixels PX and receives light from the detection object. The pixels PX are disposed in a matrix in the detection area DA. The pixels PX include light detection sensors, which are photodiodes, and respectively output electric signals corresponding to light irradiating the respective photodiodes. Each pixel PX outputs an electric signal corresponding to the light irradiating the pixel PX to the signal line selecting circuit 21 as a detection signal Vdet. The light detection device 1 may be capable of detecting biological data, such as a blood vessel image of a finger and a palm, a pulse wave, a pulse, and a blood-oxygen saturation, based on the detection signal Vdet from each pixel PX. Each pixel PX performs detection in accordance with a gate drive signal Vgcl supplied from the gate line driving circuit 20.

The gate line driving circuit 20 and the signal line selecting circuit 21 are provided in the frame area PA. Specifically, as shown in FIG. 1, the gate line driving circuit 20 is provided in an area of the frame area PA extending along the extension direction of the signal line SGL. The signal line selecting circuit 21 is provided in an area of the frame area PA extending along the extension direction of the gate line GCL, and is provided in an area in the lower side of the substrate 110.

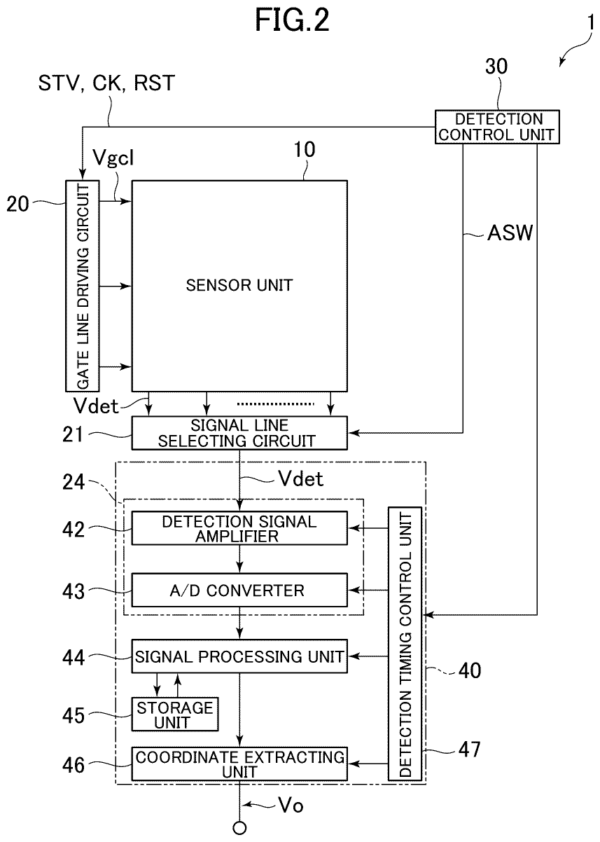

FIG. 2 is a block diagram showing an outline of a circuit configuration of the light detection device according to the present embodiment. As shown in FIG. 2, the light detection device 1 includes an output control unit 30 and a detection unit 40. Some or all of the functions of the detection control unit 30 are included in the control circuit 26. Further, some or all of the functions of the detection unit 40 other than the detection circuit 24 are included in the control circuit 26.

The detection control unit 30 is a circuit that supplies control signals to the gate line driving circuit 20, the signal line selecting circuit 21, and the detection unit 40, and controls these operations. The detection control unit 30 supplies control signals, such as a start signal STV, a clock signal CK, and a reset signal RST, to the gate line driving circuit 20. The detection control unit 30 supplies control signals, such as a selection signal ASW, to the signal line selecting circuit 21. The gate line driving circuit 20 drives the gate line GCL based on the control signals. The gate line driving circuit 20 sequentially or simultaneously selects a plurality of gate lines GCL, and supplies a gate drive signal Vgcl to the selected gate line GCL. In this manner, the gate line driving circuit 20 selects a pixel PX connected to the gate line GCL. The signal line selecting circuit 21 is a switching circuit that sequentially or simultaneously selects a plurality of signal lines SGL. The signal line selecting circuit 21 is a multiplexer, for example. The signal line selecting circuit 21 connects the selected signal line SGL with the detection circuit 24 based on the selection signal ASW supplied from the detection control unit 30. This enables the signal line selecting circuit 21 to output a detection signal Vdet of the pixel PX to the detection unit 40.

The detection unit 40 includes the detection circuit 24, a signal processing unit 44, a storage unit 45, a coordinate extracting unit 46, and a detection timing control unit 47. The detection timing control unit 47 controls the detection circuit 24, the signal processing unit 44, and the coordinate extracting unit 46 to operate in synchronization based on the control signal supplied from the detection control unit 30.

The detection circuit 24 is an analog front end circuit (AFE), for example. The detection circuit 24 is a signal processing circuit having at least functions of a detection signal amplifier 42 and an A/D converter 43. The detection signal amplifier 42 amplifies the detection signal Vdet. The A/D converter 43 converts an analog signal from the detected signal amplifier 42 into a digital signal. The signal processing unit 44 is a logic circuit that detects a predetermined physical quantity entered into the sensor unit 10 based on the output signal of the detection circuit 24. When a detection target, such as a finger and a palm, comes into contact with or is close to the detection surface, the signal processing unit 44 detects unevenness of the surface of the finger and the palm based on the signal from the detection circuit 24. Further, the signal processing unit 44 detects biological data, such as a blood vessel image of a finger and a palm, a pulse wave, a pulse, and a blood-oxygen saturation, based on a signal from the detection circuit 24. The storage unit 45 temporarily stores the signal calculated by the signal processing unit 44. The storage unit 45 may be a random access memory (RAM) or a register circuit, for example. The coordinate extracting unit 46 is a logic circuit that obtains detection coordinates of unevenness of a surface of a finger and a palm, for example, when the signal processing unit 44 detects contact or approach of the finger or the palm. The coordinate extracting unit 46 is a logic circuit that obtains detection coordinates of blood vessels of a finger and a palm, for example. The coordinate extracting unit 46 combines detection signals Vdet from the respective pixels PX of the sensor unit 10 to generate two-dimensional information indicating the shape of the unevenness of the surface of the finger and the palm, for example. The coordinate extracting unit 46 may not calculate the detection coordinates but output the detection signal Vdet as the sensor output Vo.

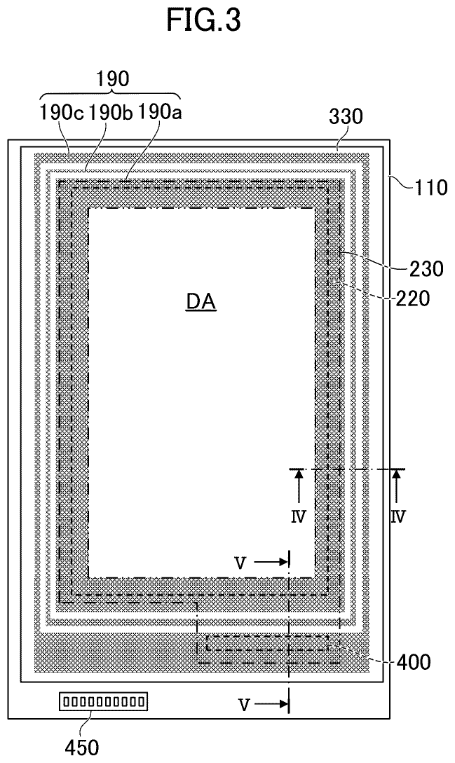

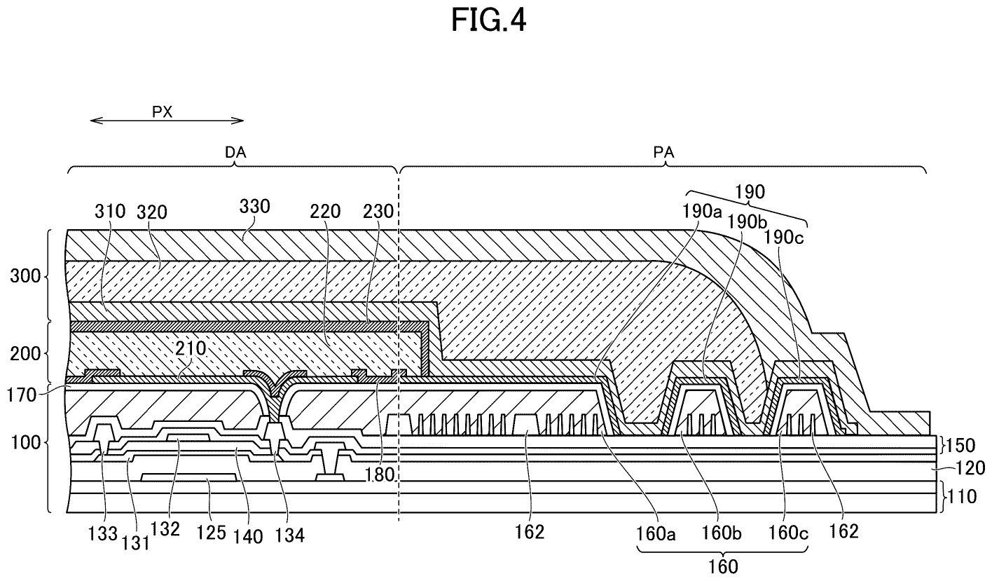

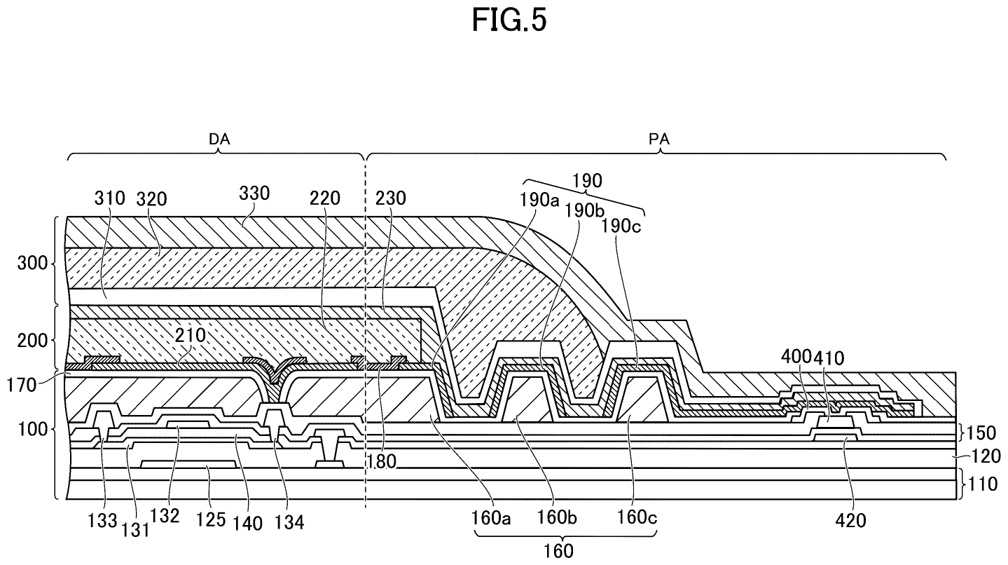

Next, the substrate 110 will be described in detail with reference to FIGS. 3 and 4. FIG. 3 is a plan view of the substrate 110 of the light detection device 1 and shows the peripheries of the main films. FIG. 4 is a cross-sectional view of the substrate 110 taken along the line IV-IV in FIG. 3. FIG. 4 shows a part of the detection area DA near the end portion and the entire frame area PA. In FIG. 4, hatching of some layers is omitted for clarity of the cross-sectional structure (the same applies to FIGS. 5, 6, 8, 9 to be described later).

In FIG. 3, the two-dot chain lines represent the border between the detection area DA and the frame area PA. The area inside the two-dot chain lines is the detection area DA, and the area outside the two-dot chain lines is the frame area PA. In the frame area PA, the substrate 110 includes a terminal portion 450 that connects the flexible printed board 500 with the substrate 110 and a common line connecting portion 400 that supplies a voltage to an upper electrode 230 to be described later. The substrate 110 has the same layer structure on the left side, the upper side, and the right side, and thus, a cross-sectional view of the substrate 110 taken along the line IV-IV in FIG. 3 will be described as an example.

As shown in FIG. 4, the light detection device 1 includes a lower structure 100 including a thin film transistor TFT, an OPD layer 200 provided on the lower structure 100, and a sealing structure 300 provided on the OPD layer 200.

The lower structure 100 includes the substrate 110 and a barrier inorganic layer 120 provided on the substrate 110. For example, the substrate 110 may have a two-layer structure of a glass substrate and a resin substrate provided thereon. The resin substrate may be formed of polyimide, for example. However, the present invention is not limited thereto, and the substrate 110 does not have a glass substrate and may be formed of only a flexible resin substrate. The barrier inorganic layer 120 may have a laminate structure including a plurality of layers. The lower structure 100 may include an additional layer 125 at the position where the thin film transistor TFT is formed.

The thin film transistor TFT includes a semiconductor layer 131, a gate electrode 132, a source electrode 133, and a drain electrode 134. A gate insulating layer 140 is provided between the semiconductor layer 131 and the gate electrode 132. A silicon oxide layer may be used as the gate insulating layer 140. An interlayer insulating layer 150 is formed on the gate electrode 132. The interlayer insulating layer 150 may have a laminate structure of a silicon nitride layer and a silicon oxide layer.

A flattening layer 160 is formed on the interlayer insulating layer 150. The flattening layer 160 may be made of a resin having excellent surface flatness, such as photosensitive acrylic. The flattening layer 160 may be removed at the part that electrically connects the OPD layer 200 and the lower structure 100. Further, a lead wire 162 may be disposed inside the flattening layer 160.

As shown in FIG. 4, the flattening layer 160 includes a central flattening portion 160a, an inner bank portion 160b, and an outer bank portion 160c. The flattening layer 160 is partially removed in the frame area PA so as to form the inner bank portion 160b and the outer bank portion 160c. The inner bank portion 160b and the outer bank portion 160c form a double bank structure in a plan view. The inner bank portion 160b and the outer bank portion 160c are formed to prevent the resin material constituting the sealing structure 300 from leaking out of the frame area PA. The central flattening portion 160a is continuously formed in the detection area DA and a portion of the frame area PA adjoining the detection area DA, that is, an inner peripheral edge portion. “Continuously” means continuing seamlessly, and the central flattening portion 160a is continuously and seamlessly formed from the detection area DA to the inner peripheral edge portion of the frame area PA.

An insulating layer 170 may be provided on the flattening layer 160. Further, an inorganic insulating layer 180 made of an inorganic material may be provided on the insulating layer 170 in the detection area DA. Such an inorganic insulating layer 180 may be referred to as a rib, a partition wall, and a bank, for example. The inorganic insulating layer 180 is an inorganic insulating layer formed of silicon nitride, for example. The inorganic insulating layer 180 may also be provided on the pixel electrode 210 included in the OPD layer 200 so as to expose the pixel electrode 210. In the cross-sectional view, the inorganic insulating layer 180 is located inside the end portion of the organic photoelectric conversion layer 220 described later.

The transparent conductive protective layers 190 are formed on the insulating layer 170 in the frame area PA. The transparent conductive protective layers 190 includes a first transparent conductive protective layer 190a, a second transparent conductive protective layer 190b, and a third transparent conductive protective layer 190c. The first transparent conductive protective layer 190a is formed so as to cover the peripheral edge portion of the central flattening portion 160a. Further, the first transparent conductive protective layer 190a covers the inner peripheral edge portion of the frame area PA over the entire circumference (see FIG. 3). The second transparent conductive protective layer 190b is formed so as to cover the inner bank portion 160b. The third transparent conductive protective layer 190c is formed so as to cover the outer bank portion 160c. The transparent conductive protective layers 190 are formed in this manner, whereby the lead wire 162 formed in the flattening layer 160 can be protected. The transparent conductive protective layers 190 may be formed of indium-based oxide. The transparent conductive protective layers 190 may be formed of indium tin oxide (ITO) among the indium-based oxides.

The OPD layer 200 is provided with the pixels PX shown in FIG. 1 arranged thereon. The OPD layer 200 includes pixel electrodes 210 on the insulating layer 170, an organic photoelectric conversion layer 220 covering the pixel electrodes 210 and reaching the frame area PA, and an upper electrode 230 on the organic photoelectric conversion layer 220.

The pixel electrodes 210 are provided corresponding to the respective pixels PX, and are electrically connected to the drain electrode 134 of the lower structure 100. The organic photoelectric conversion layer 220 functions as a photoelectric conversion layer. The organic photoelectric conversion layer 220 is continuously formed on the inner peripheral edge portion of the detection area DA and the frame area PA. The organic photoelectric conversion layer 220 is formed on the first transparent conductive protective layer 190a at the inner peripheral edge portion of the frame area PA. The upper electrode 230 is a common electrode that is provided across the pixels PX.

The sealing structure 300 includes a first inorganic layer 310 provided on the upper electrode 230, a resin layer 320 provided on the first inorganic layer 310, and a second inorganic layer 330 provided on the resin layer 320. The resin layer 320 may be made of a material having high transmittance and low moisture permeability.

The end portions of the first inorganic layer 310, the resin layer 320, and the second inorganic layer 330 are located in the frame area PA. In particular, the end portion of the second inorganic layer 330 is located near the edge of the substrate 110 (see FIG. 3). The second inorganic layer 330 is in contact with the first inorganic layer 310 in the frame area PA. As described above, the plurality of inorganic layers prevent moisture from entering the organic photoelectric conversion layer 220 from the outside in the sealing structure 300.

Next, with reference to FIG. 5, a cross-sectional view of the light detection device taken along the line V-V in FIG. 3 will be described. The layers having the same functions as the layers described with reference to FIG. 4 are denoted by the same reference signs, and the detailed explanation thereof is omitted. In the following, the configuration different from the configuration described with reference to FIG. 4 will be mainly described.

The common line connecting portion 400 is provided on the interlayer insulating layer 150 in the frame area PA and connected to the common line 410. The common line 410 supplies a common voltage to the upper electrode 230 via the common line connecting portion 400. As such, the common line connecting portion 400 and the upper electrode 230 need to be electrically connected to each other. A line 420 is provided on the gate insulating layer 140.

Unlike the example in FIG. 4, the third transparent conductive protective layer 190c is continuously formed so as to cover not only the outer bank portion 160c but also the common line connecting portion 400. Further, the upper electrode 230 is continuously formed from the detection area DA to the common line connecting portion 400 of the frame area PA (see FIG. 3). The third transparent conductive protective layer 190c has conductivity, and thus the upper electrode 230 and the common line connecting portion 400 may be electrically connected even if the third transparent conductive protective layer 190c is provided between the common line connecting portion 400 and the upper electrode 230. With this configuration, even if the common line connecting portion 400 and the upper electrode 230 are not in direct contact with each other, a common voltage can be supplied to the upper electrode 230. When being in contact with the third transparent conductive protective layer 190c disposed on the outermost periphery, the upper electrode 230 is electrically connected to the common line connecting portion 400, and thus may not be formed on the common line connecting portion 400.

Referring back to FIG. 3, the main layers when the substrate 110 is viewed in plan will be described. In FIG. 3, an area with dot patterns represents the transparent conductive protective layers 190. The transparent conductive protective layers 190 are formed such that three films having a rectangular frame shape surround the detection area DA, and includes a first transparent conductive protective layer 190a, a second transparent conductive protective layer 190b, and a third transparent conductive protective layer 190c from the inside. The transparent conductive protective layers 190 are disposed inside the second inorganic layer 330. Preferably, all of the transparent conductive protective layers 190 are disposed inside the second inorganic layer 330. The inner peripheral edge of the first transparent conductive protective layer 190a coincides with the inner peripheral edge of the frame area PA, and the first transparent conductive protective layer 190a is formed so as to surround the detection area DA.

The common line connecting portion 400 is provided in the lower side area of the substrate 110, The third transparent conductive protective layer 190c is a film formed in the rectangular frame-shaped area. The widths of the area are different on the four sides, and in particular, the width of the lower side is wider than the other three sides so as to be formed to cover the common line connecting portion 400.

The organic photoelectric conversion layer 220 is formed in a rectangular area indicated by broken lines and covers the detection area DA and inner peripheral edge portion of the frame area PA. The peripheral edge portion of the organic photoelectric conversion layer 220 is disposed inside the first transparent conductive protective layer 190a in a plan view. The upper electrode 230 is formed in an area indicated by dashed-dotted lines and covers the detection area DA and inner peripheral edge portions of the frame area PA. The peripheral edge portion of the upper electrode 230 is located further outside of the peripheral edge portion of the organic photoelectric conversion layer 220, and the upper electrode 230 covers the entire organic photoelectric conversion layer 220. The peripheral edge portion of the upper electrode 230 is disposed inside the first transparent conductive protective layer 190a in a plan view.

The second inorganic layer 330 is formed in an area indicated by solid lines. The transparent conductive protective layers 190, the organic photoelectric conversion layer 220, and the upper electrode 230 are disposed inside the second inorganic layer 330 in a plan view.

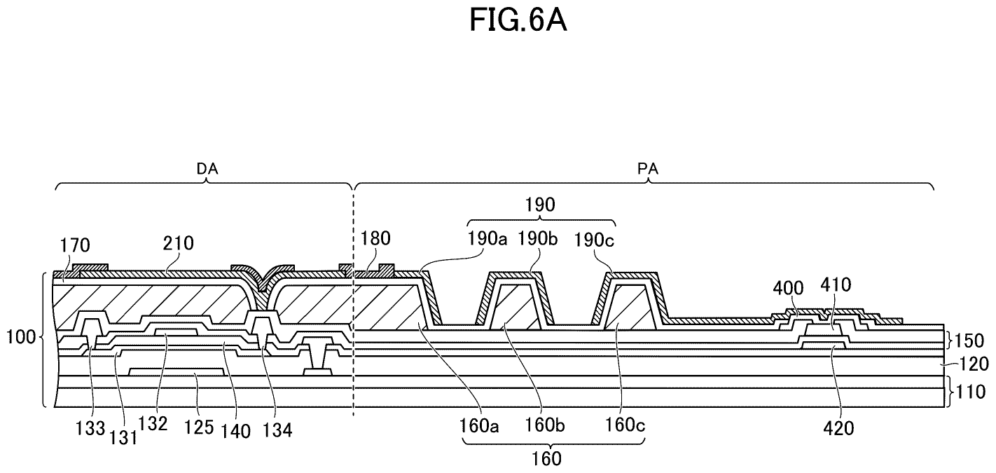

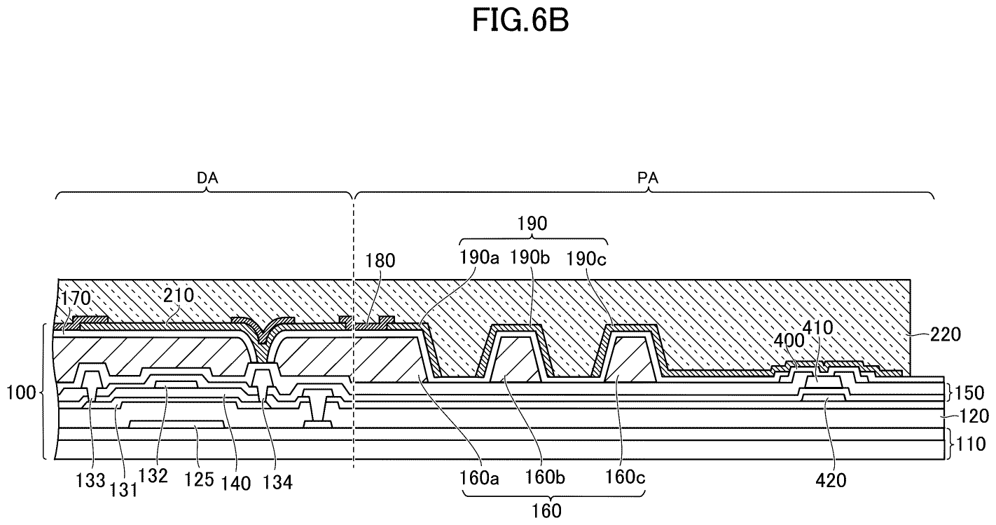

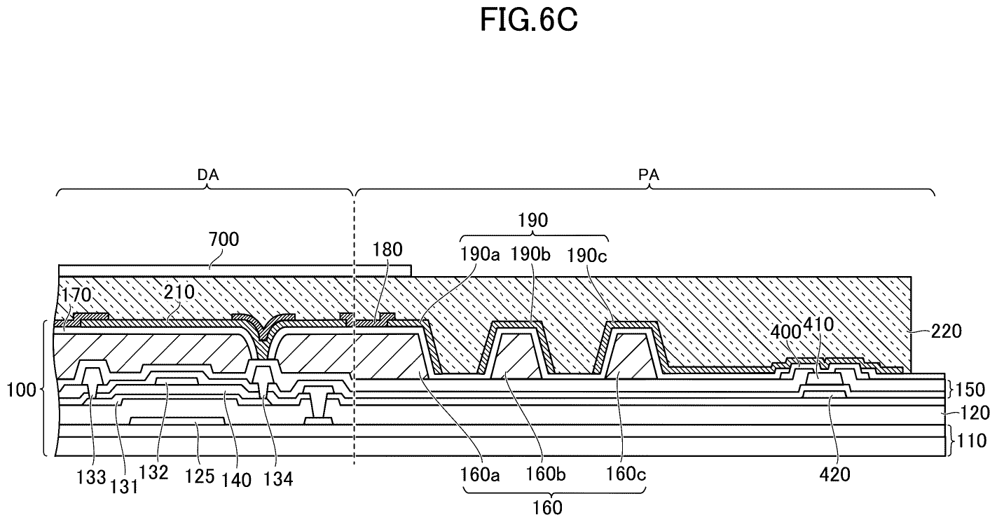

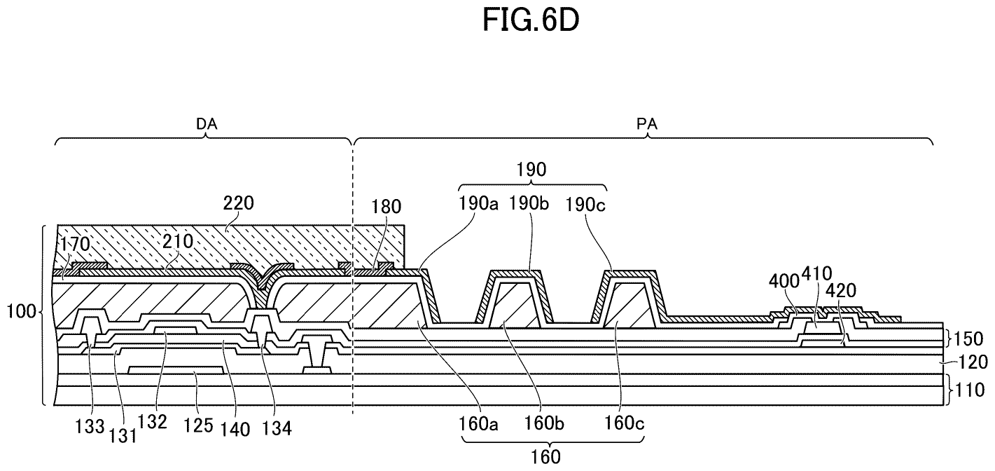

Next, the processing of manufacturing the substrate 110 of the present embodiment will be described in details referring to the drawings. FIGS. 6A to 6D are diagrams indicating methods for manufacturing the substrate 110 of the embodiment of the present invention. The cross-sectional view of the substrate 110 taken along the line V-V in FIG. 3 is taken as an example.

As shown in FIG. 6A, the lower structure 100, the common line connecting portion 400, the common line 410, and the line 420 are formed on the substrate 110. The substructure 100 is formed by repeating a general photolithographic process a plurality of times. A variety of types of such method are well known, and thus, detailed description thereof will be omitted in this specification.

Subsequently, a plurality of pixel electrodes 210 are formed on the lower structure 100. The transparent conductive protective layer 190 is then formed on the lower structure 100 in the frame area PA. The flattening layer 160 and the common line connecting portion 400 are covered by the transparent conductive protective layer 190. In a case where the materials of the pixel electrodes 210 and the transparent conductive protective layer 190 are the same, they may be simultaneously formed on the lower structure 100. This enables to reduce the manufacturing steps. Subsequently, an inorganic insulating layer 180 serving as a separation wall between the plurality of pixel electrodes 210 is formed. The common lithographic method may also be used in forming the inorganic insulating layer 180.

Next, as shown in FIG. 6B, the organic photoelectric conversion layer 220 is continuously formed over the detection area DA and the frame area PA. The organic photoelectric conversion layer 220 may be formed by vapor deposition or by a coating using a solvent dispersion or a slit coater. With this process, the organic photoelectric conversion layer 220 is formed on the flattening layer 160 and the common line connecting portion 400 on the transparent conductive protective layer 190.

As shown in FIG. 6C, a mask 700 is then formed to cover the detection area DA and a part of the frame area PA where the transparent conductive protective layer is formed. In the cross-sectional view, the end portion of the mask 700 is disposed in an area where the central flattening portion 160a of the inner peripheral edge portion of the frame area PA and the first transparent conductive protective layers 190a overlap with each other. The mask 700 may also be formed by using a common lithographic method.

Next, as shown in FIG. 6D, the organic photoelectric conversion layer 220 is etched using the mask 700. With this process, the organic photoelectric conversion layer 220 can be continuously formed on the detection area DA and the inner peripheral edge portions of the frame area PA.

As described above, in the present embodiment, the transparent conductive protective layers 190 are formed on the frame area PA before the organic photoelectric conversion layer 220 is formed, and thus, the flattening layer 160 and the common line connecting portion 400 can be protected even when the etching conditions are increased. The organic photoelectric conversion layer 220 is in contact with the first transparent conductive protective layer 190a, which allows moisture to pass therethrough, but is not in contact with the second transparent conductive protective layer 190b and the third transparent conductive protective layer 190c and is disposed inside the second inorganic layer 330, and thus can block moisture.

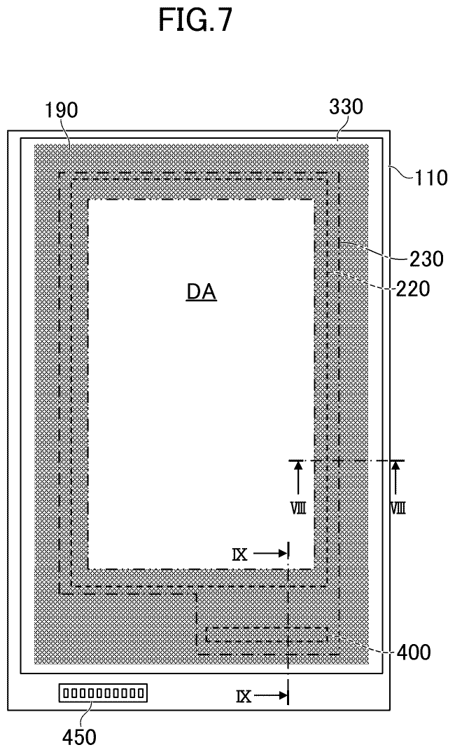

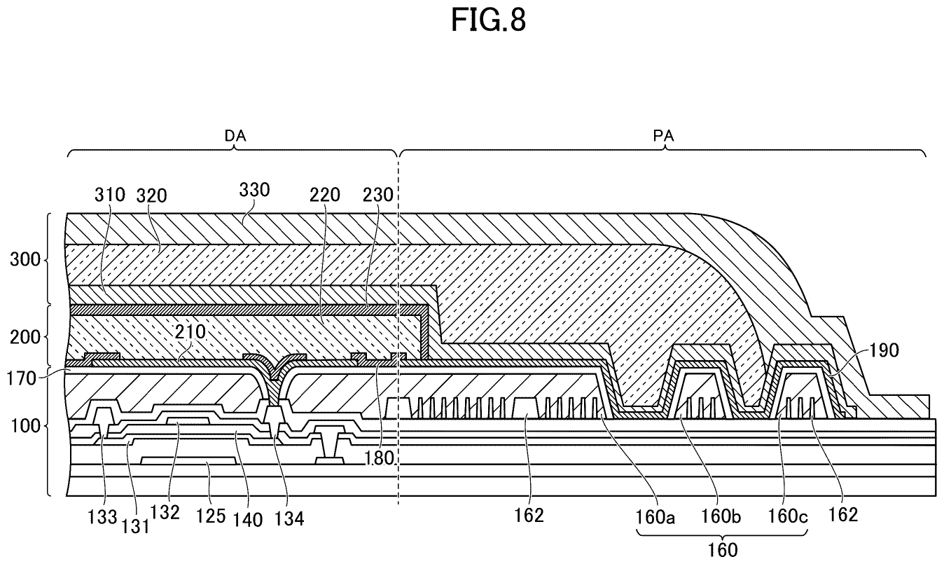

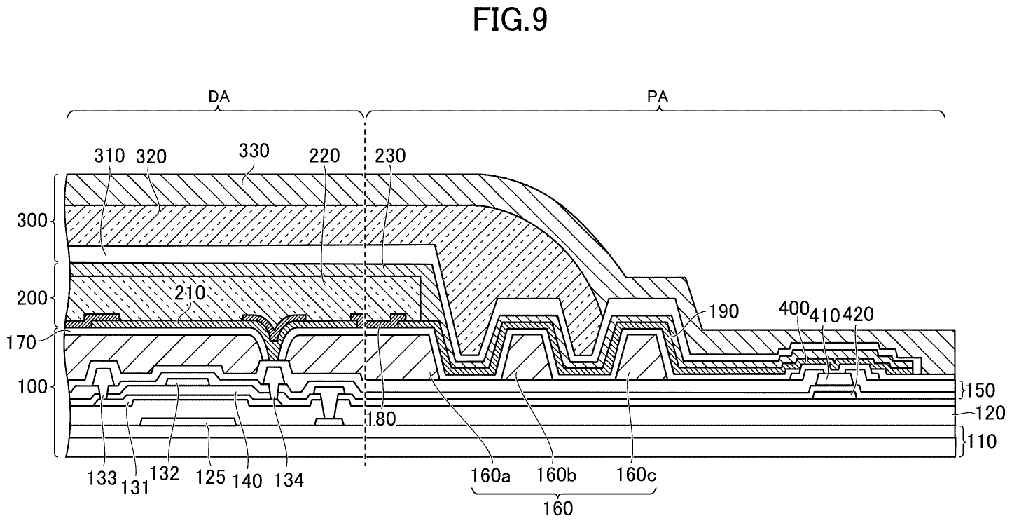

Referring to FIGS. 7 to 9, the substrate 110 according to a modification of the present embodiment will be described. FIG. 7 is a plan view of the substrate 110 of the modification of the light detection device 1 and represents the peripheries of the main films. FIG. 8 is a cross-sectional view of the light detection device taken along the line VIII-VIII in FIG. 7. FIG. 9 is a cross-sectional view of the light detection device taken along the line IX-IX in FIG. 7. FIGS. 8 and 9 show the parts corresponding to the cross-sectional views shown in FIGS. 4 and 5. The layers having the same functions as the layers described with reference to FIGS. 5 and 6 are denoted by the same reference signs, and the detailed explanation thereof is omitted. In the following, the configuration different from the configuration described with reference to FIGS. 5 and 6 will be mainly described.

As shown in FIG. 8, the transparent conductive protective layer 190 is continuously formed from the inner peripheral edge portion of the frame area PA to the outer bank portion 160c. That is, the central flattening portion 160a, the inner bank portion 160b, and the outer bank portion 160c are covered by one transparent conductive protective layer 190. As shown in FIG. 9, the transparent conductive protective layer 190 is continuously formed from the inner peripheral edge portion of the frame area PA to the common line connecting portion 400. That is, the central flattening portion 160a, the inner bank portion 160b, the outer bank portion 160c, and the common line connecting portion 400 are covered by one transparent conductive protective layer 190.

As shown in FIG. 7, the transparent conductive protective layer 190 is formed in an area with dot patterns in the substrate 110 according to the modification. The transparent conductive protective layer 190 is formed in a rectangular frame-shaped area surrounding the frame area PA. The peripheral edges of the organic photoelectric conversion layer 220 and the upper electrode 230 are disposed inside the transparent conductive protective layer 190 in a plan view.

Such a configuration of the present modification can increase the area of the same potential as that of the upper electrode 230 and the common line connecting portion 400, thereby providing an effect of stabilization.

While there have been described what are at present considered to be certain embodiments of the invention, it will be understood that various modifications may be made thereto, and it is intended that the appended claims cover all such modifications as fall within the true spirit and scope of the invention.

What is claimed is:

1. A light detection device comprising:
a lower structure that is provided in a detection area and in a frame area surrounding the detection area;
a plurality of pixel electrodes that are provided in array on the lower structure in the detection area;
an organic photoelectric conversion layer that is provided on the plurality of pixel electrodes and continuously formed on the detection area and a part of the frame area;
an upper electrode that is provided on the organic photoelectric conversion layer; and
a transparent conductive protective layer that is provided on the lower structure in at least a part of the frame area and at least partially disposed under a part of a peripheral edge portion of the organic photoelectric conversion layer formed in the frame area.

2. The light detection device according to claim 1, wherein
the transparent conductive protective layer is provided so as to surround the detection area, and
the entire peripheral edge portion of the organic photoelectric conversion layer is disposed in the frame area.

3. The light detection device according to claim 1, further comprising a sealing structure that includes a first inorganic layer, a resin layer, and a second inorganic layer, the first inorganic layer being provided on the upper electrode in the detection area and the frame area, the resin layer being provided on the first inorganic layer, the second inorganic layer being provided on the resin layer, wherein
the transparent conductive protective layer is disposed inside the second inorganic layer in a plan view.

4. The light detection device according to claim 1, wherein
a common line connecting portion electrically connected to a common line is provided on a surface of the lower structure in the frame area,
a part of the transparent conductive protective layer covers at least a part of the common line connecting portion, and
the part of the transparent conductive protective layer that covers the common line connecting portion is electrically connected to the upper electrode.

5. The light detection device according to claim 1, wherein
the plurality of pixel electrodes and the transparent conductive protective layer are made of a same material.

6. The light detection device according to claim 1, wherein
the transparent conductive protective layer is made of indium-based oxide.

7. The light detection device according to claim 1, wherein
the transparent conductive protective layer is made of indium tin oxide (ITO).

8. A method for manufacturing a light detection device, comprising the steps of:
forming a lower structure in a detection area and in a frame area surrounding the detection area;
forming a plurality of pixel electrodes in array on the lower structure in the detection area;
forming a transparent conductive protective layer in at least a part of the frame area on the lower structure so as to be adjacent to the detection area;
etching the organic photoelectric conversion layer with a mask that covers the detection area and a part of an area in the frame area in which the transparent conductive protective layer is formed; and
forming an upper electrode on the etched organic photoelectric conversion layer.
